(19) United States
(12) Patent Application Publication
(10) Pub. No.: US 2007/0105053 A1
(43) Pub. Date: May 10, 2007

(54) Method of manufacturing semiconductor device

(75) Inventors: Shinichi Watanuki, Kanagawa (JP); Toshinori Fukai, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/585,168

(22) Filed: Oct. 24, 2006

(30) Foreign Application Priority Data
Oct. 25, 2005 (JP) 2005-309900

(51) Int. Cl. G03F 7/00

(52) U.S. Cl. 430/313

(57) ABSTRACT

Aiming at improving productivity of the semiconductor devices and at improving the product yield, a method of the present invention fabricates a semiconductor device by using, as a photomask, a first photomask 106 having a first rectangular pattern 104a obtained by dividing a mask pattern, and a second photomask 108 having a second rectangular pattern 104b obtained by dividing the mask pattern, wherein the method includes a first step processing a sacrificial film formed on a semiconductor substrate, using the first photomask 106 to thereby form therein a first rectangular pattern 104a; a second step processing the sacrificial film using the second photomask 108 to thereby form therein a second rectangular pattern 104b; and a third step etching the film formed on the semiconductor substrate, using, as a mask, the sacrificial film processed as having the rectangular pattern 104a and the second rectangular pattern 104b formed therein.

This application is based on Japanese patent application No. 2005-309900 the content of which is incorporated hereinto by reference.

### BACKGROUND

1. Technical Field

The present invention relates to a method of manufacturing a semiconductor device using a plurality of photomasks.

2. Related Art

Various methods have been adopted in conventional fabrication processes of semiconductor devices aiming at transferring mask patterns exactly as designed.

A method described in Japanese Laid-Open Patent Publication No. 8-227140 is one of such methods. The publication discloses a method of manufacturing a semiconductor device, by which a mask pattern is divided into the orthogonal directions (x-direction and y-direction) so as to avoid contradiction in phase allocation, and thereby two photomasks having the individual mask patterns are used. The technique disclosed in the publication is such as partitioning “0” regions and “n” regions causing a 180° phase inversion therefrom, so as to avoid contradictory phase allocation.

The conventional technique disclosed in the above-described, Japanese Laid-Open Patent Publication No. 8-227140, however, has a room for further improvement in the aspects below.

The method described in the publication is a method of avoiding phase contradiction, by dividing the mask pattern into “0” regions and “n” regions. As a consequence, some portions may contain mask patterns extending in the same direction and closely adjacent to each other, and may result in degraded productivity of the semiconductor devices and lowered product yield.

That is, for the case where mask patterns extending in the same direction are closely adjacent to each other as shown in FIG. 18A, it is necessary to use a photomask having a mask pattern 12 shown in FIG. 18B, in order to transfer the mask pattern as designed. More specifically, it is necessary to provide optical proximity correction (OPC) typically by forming inner serif portions 14 and outer serif portions 16 at the kinked portions of the mask pattern 12, making the mask pattern geometrically more complicated.

The mask pattern geometrically more complicated needs a longer time for the pattern drawing, so that cost of the mask may increase, fabrication process of the mask may become lengthy, and consequently productivity of the semiconductor device may degrade. It has also been anticipated that thus-complicated OPC process may produce unexpected patterns, and may degrade yield of the products.

What is worse, the mask pattern has been becoming more micronized as the semiconductor devices shrinks. With such trends in micronization of the mask pattern, there has been raised a need for further complicated OPC process, in order to transfer the mask pattern exactly as designed. In particular, this trend is distinct for the portions where the mask pattern shown in FIG. 18A is connected.

It has therefore been desired to improve productivity of the semiconductor devices and the product yield, through reduction in the OPC process.

In addition, one of the photomasks having the mask patterns obtained by division in the orthogonal directions (x-direction and y-direction), as disclosed in Japanese Laid-Open Patent Publication No. 8-227140, contains a pattern composed of a plurality of rectangular patterns as shown in FIG. 1A, showing only a limited degree of reduction in the OPC process.

### SUMMARY OF THE INVENTION

According to the present invention, there is provided a method of manufacturing a semiconductor device including a step of transferring a mask pattern using a photomask onto a sacrificial film on a semiconductor substrate, and etching a film formed on the semiconductor substrate using the sacrificial film as a mask,

wherein, as the photomask, a first photomask having a first rectangular pattern obtained by dividing the mask pattern, and a second photomask having a second rectangular pattern obtained by dividing the mask pattern, are used, and

the step includes three following steps of:

a first step processing the sacrificial film using the first photomask to thereby form a first rectangular pattern;

a second step processing the sacrificial film using the second photomask to thereby form a second rectangular pattern; and

a third step etching the film using, as a mask, the sacrificial film processed as having the first and second rectangular patterns formed therein.

According to this invention, the mask pattern is divided into the rectangular patterns. As a consequence, it is no more necessary to carry out the complicated OPC process which has been adopted to the kinked portions of the mask pattern. Therefore, the mask pattern drawing takes only a shorter time, and productivity of the semiconductor device improves. What is better, there is no need of carrying out the complicated OPC process, so that the product yield improves.

It is to be understood herein that the first rectangular pattern and the second rectangular pattern obtained by dividing the mask pattern have square geometries, and have no irregularities nor kinks over the entire span of each edge.

The sacrificial film denoted herein means a film which does not remain in the final structure.

According to the present invention, there is provided a method of manufacturing a semiconductor device, capable of improving productivity of the semiconductor devices, and of improving the product yield.

### BRIEF DESCRIPTION OF THE DRAWINGS

The above and other objects, advantages and features of the present invention will be more apparent from the following description taken in conjunction with the accompanying drawings, in which:

FIG. 1 is a top view schematically showing a region having a plurality of transistors arranged therein, in embodiments;

FIG. 2 is a top view schematically showing a phase-shifting mask in a first embodiment;

FIGS. 3A and 3B are top views schematically showing a first photomask and a second photomask, respectively, in the first embodiment;

FIGS. 4A to 9B are schematic views sequentially showing process steps of a method of manufacturing a semiconductor device of the first embodiment, wherein the series-A drawings are top views, and the series-B drawings are correspondent sectional views;

FIG. 10 is a top view schematically showing a relation between a chip on a semiconductor wafer and directions of gate patterns;

FIG. 11 is a top view schematically showing a binary mask in a second embodiment;

FIGS. 12A and 12B are top views schematically showing the first photomask and the second photomask, respectively, in the second embodiment;

FIGS. 13A to 17B are schematic views sequentially showing process steps of a method of manufacturing a semiconductor device of the second embodiment, wherein the series-A drawings are top views, and the series-B drawings are correspondent sectional views; and

FIGS. 18A and 18B are schematic drawings showing optical proximity correction (OPC) adopted to kinked portions of a mask pattern in a conventional method of manufacturing a semiconductor device.

### DETAILED DESCRIPTION OF THE PREFERRED EMBODIMENT

The invention will be now described herein with reference to an illustrative embodiment. Those skilled in the art will recognize that many alternative embodiments can be accomplished using the teachings of the present invention and that the invention is not limited to the embodiment illustrated for explanatory purposes.

Paragraphs below will describe embodiments of the present invention referring to the attached drawings. It is to be noted that, in all drawings, any similar components will be added with similar reference numerals, and the explanation therefor will not be repeated.

The method of manufacturing a semiconductor device of the embodiments includes a step of transferring a mask pattern using a photomask onto a sacrificial film on a semiconductor substrate, and etching a film (polysilicon film 114) formed on the semiconductor substrate using the sacrificial film as a mask. As the photomask, a first photomask (106 or 142) having a first rectangular pattern (104a or 141a) obtained by dividing the mask pattern, and a second photomask (108 or 144) having a second rectangular pattern (104b or 141b) obtained by dividing the mask pattern, are used.

The above-described step of etching the film formed on the semiconductor substrate includes three following steps:
(i) a first step processing the sacrificial film using the first photomask (106 or 142) to thereby form the first rectangular patterns (104a, 141a);
(ii) A second step processing the sacrificial film using the second photomask (108 or 144) to thereby form the second rectangular pattern (104b or 141b); and
(iii) a third step etching the film (polysilicon film 114) using, as a mask, the sacrificial film processed as having the first and second rectangular patterns formed therein.

The sacrificial film herein includes a hard mask (first hard mask 116 and second hard mask 118), a first resist film 120, and a second resist film 126.

Paragraphs below will describe embodiments of the present invention, referring to the first embodiment and the second embodiment. These embodiments will deal with the cases where gate patterns are formed.

### First Embodiment

The explanation begins with a gate pattern obtainable by the method of manufacturing a semiconductor device according to the first embodiment.

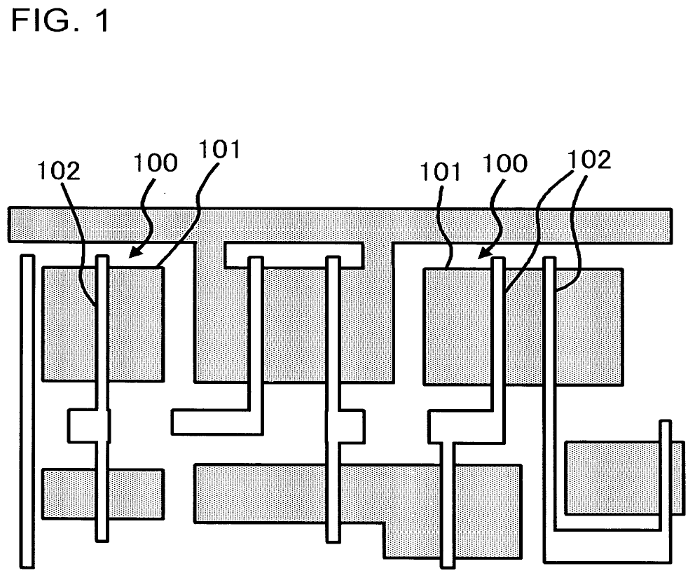

FIG. 1 shows a region having a plurality of transistors 100 arranged therein. Each transistor 100 has a source region and a drain region formed in impurity-diffused layers 101 in a semiconductor substrate. Gate patterns 102 are formed so as to extend across the impurity-diffused layers 101. Each of the gate patterns 102 corresponds to a gate electrode of the transistor 100 on the impurity-diffused layers 101.

As shown in FIG. 1, all of the gate patterns 102 are arranged so as to align the longitudinal direction thereof with the vertical direction of FIG. 1.

This embodiment will explain a case using, as a photomask, a Levenson-type, phase-shifting mask, although not limited thereto, to thereby form the gate patterns 102.

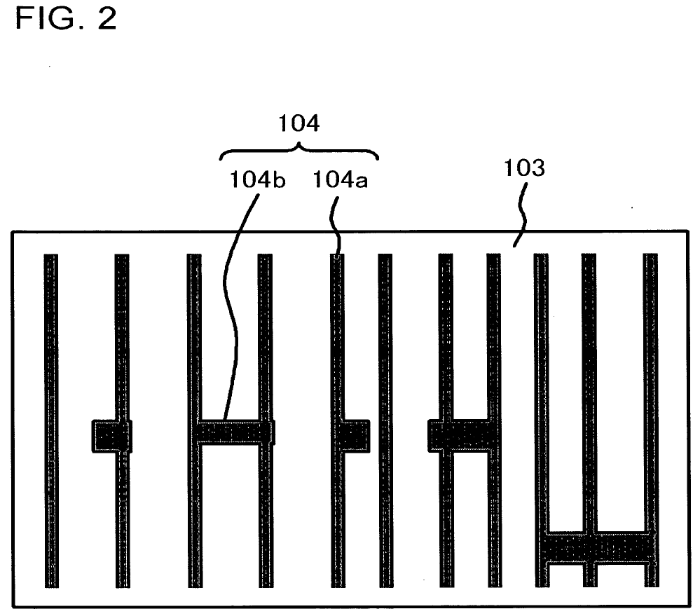

First, as shown in FIG. 2, a Levenson-type, phase-shifting mask 103 having a mask pattern 104, capable of forming desired gate patterns 102 and so forth in a semiconductor device, is designed.

The mask pattern 104 which acts as a light-intercepting region is composed of a first rectangular pattern 104a and a second rectangular pattern 104b. The first rectangular pattern 104a and the second rectangular pattern 104b are configured as being orthogonally crossed with each other. The first rectangular pattern 104a and the second rectangular pattern 104b may partially overlap.

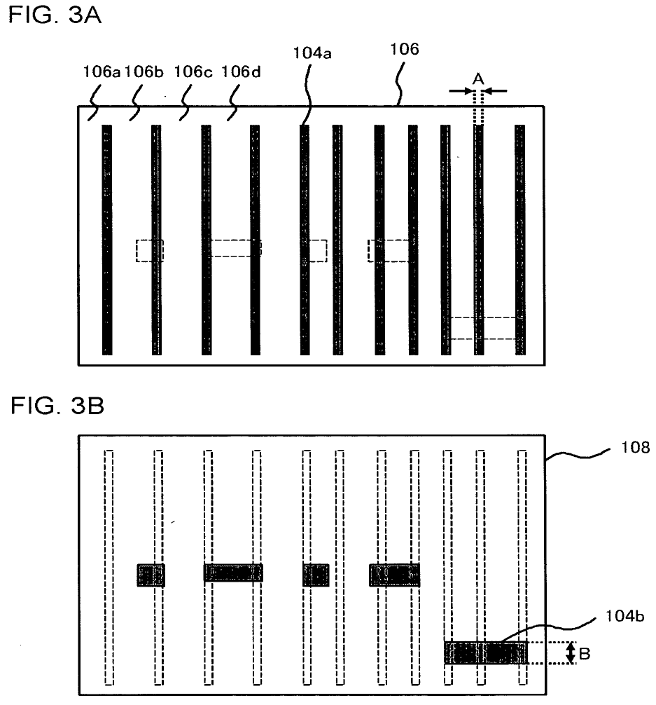

The phase-shifting mask 103 is divided into a first photomask 106 (FIG. 3A) having the first rectangular pattern 104a formed therein, and a second photomask 108 (FIG. 3B) having the second rectangular pattern 104b formed therein. The first rectangular pattern 104a and the second rectangular pattern 104b are designed by general optical simulation or causal analysis. As shown in FIGS. 3A and 3B, the minimum value of width “A” of the rectangular pattern 104a measured in the perpendicular to the direction of the longitudinal direction thereof is designed as being smaller than the minimum value of width “B” of the second rectangular pattern 104b measured in the perpendicular to the direction of the longitudinal direction thereof.

As shown in FIG. 3A, the first photomask 106 has “0” regions 106a, 106c allowing light to pass therethrough without modification, and n regions 106b, 106d allowing the light to pass therethrough with a 180° phase inversion, formed side by side while placing the first rectangular pattern 104a in between. The first rectangular pattern 104a and the second rectangular pattern 104b may be subjected to bias correction if necessary, and may further undergo the OPC process at the end portions thereof. The second rectangular pattern 104b is not necessarily a phase-shifting mask, because it contains no minimum-width pattern of the gate patterns (B>A), and instead may be an ordinary binary mask.

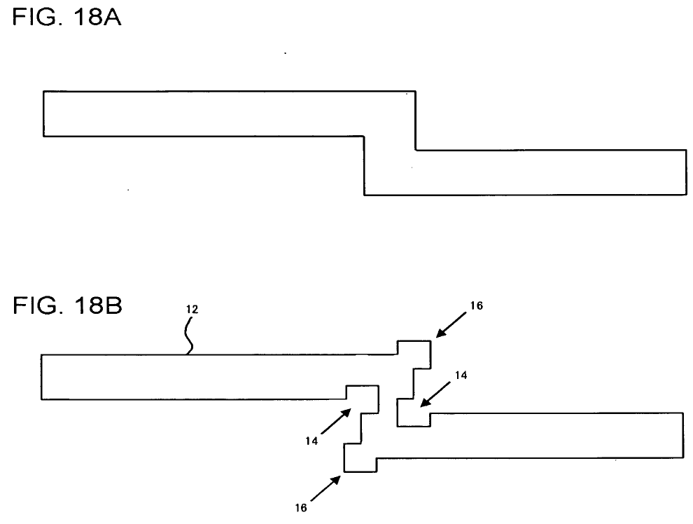

As is clear from the above, neither the first rectangular pattern 104a nor the second rectangular pattern 104b contains the pattern composed of a plurality of rectangles as shown in FIG. 18A, so that the OPC process for mask fabrication can considerably be simplified. As a consequence, the mask pattern drawing is simplified, resulting in improvements in productivity of the semiconductor devices and in the product yield.

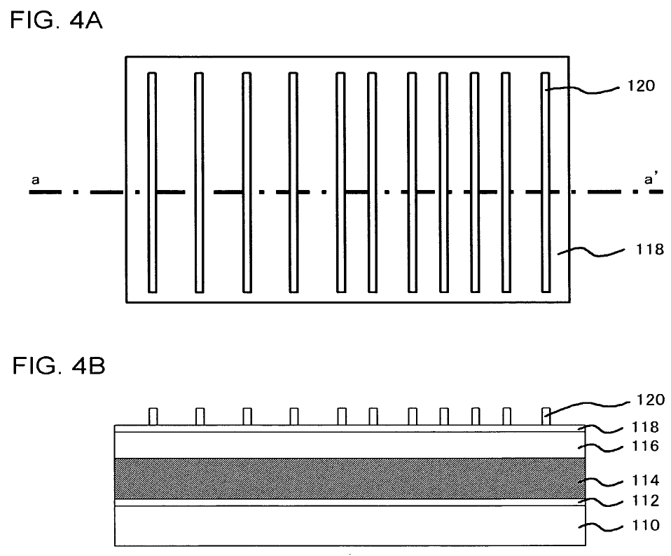

Next paragraphs will describe a method of manufacturing a semiconductor device using the photomasks having such first rectangular pattern 104a and the second rectangular pattern 104b, referring to FIG. 4A to FIG. 9B. In these drawings, the series-A drawings are top views obtained in the method of manufacturing a semiconductor device, and the series-B drawings are correspondent sectional views taken along line a-a′ in the top views of series-A.

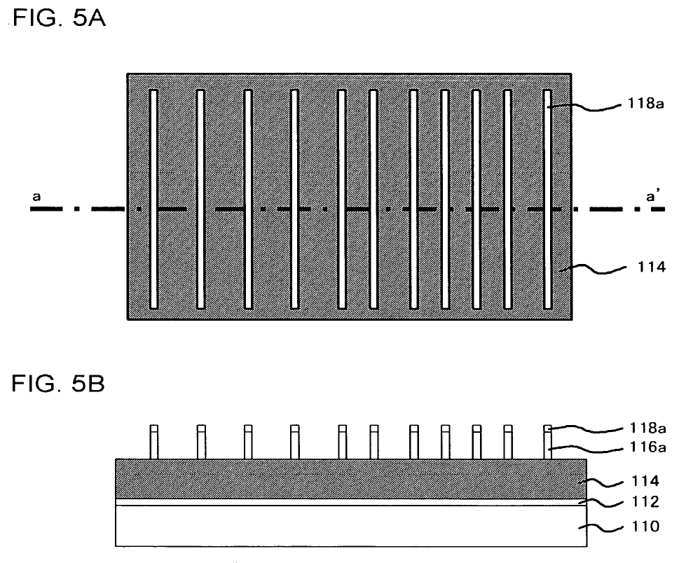

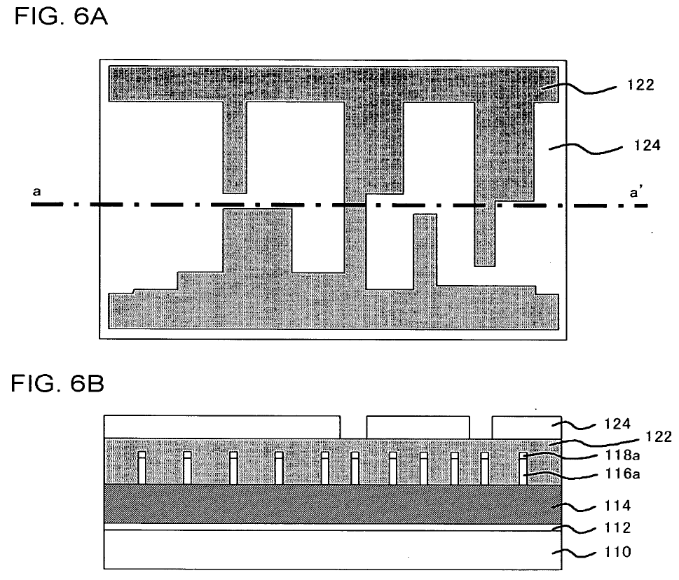

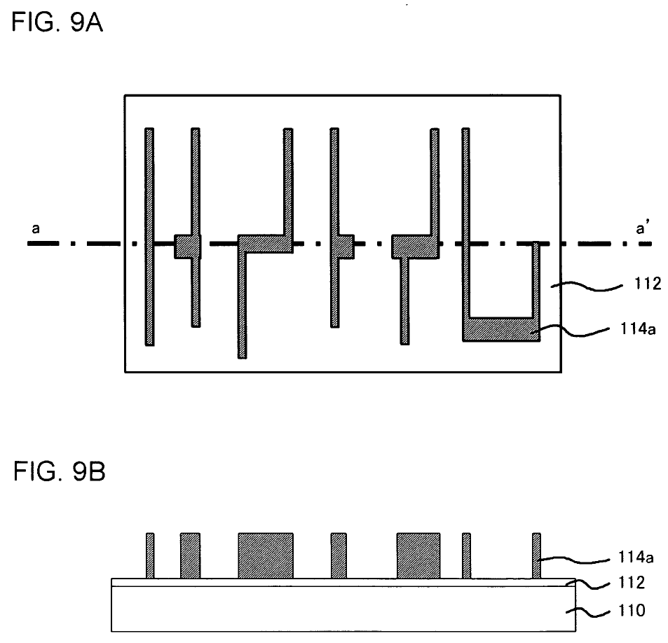

The method of manufacturing a semiconductor device of this embodiment includes three following steps:
(i) a first step forming the first resist film 120 on the hard mask (first hard mask 116, second hard mask 118) formed on the film (polysilicon film 114), exposing the first resist film 120 through the first photomask 106 so as to transfer the first rectangular pattern 104a, and etching the hard mask using, as a mask, the first resist film 120 having the first rectangular pattern 104a transferred therein (FIGS. 4A to 5B);
(ii) a second step forming the second resist film so as to cover the hard mask already etched, exposing the second resist film through the second photomask 108 so as to transfer the second rectangular pattern 104b, to thereby form the second resist film 126 having the second rectangular pattern 104b transferred therein, on the film (polysilicon film 114), while retaining thereon a part of the hard mask having the first rectangular pattern 104a transferred therein (FIGS. 6A to 8B); and
(iii) a third step etching the film (polysilicon film 114), using, as masks, the second resist film 126 and the hard mask (FIG. 9).

In this embodiment, the hard masks (first hard mask 116, second hard mask 118), the first resist film 120, a resist film 124, the second resist film 126 and so forth are used as the sacrificial film.

The above-described method of manufacturing a semiconductor device will be detailed below.

First, a gate oxide film 112, the polysilicon film 114 and the hard mask are sequentially stacked on a semiconductor substrate 110. In this embodiment, an exemplary case where the hard mask is composed of the first hard mask 116 and the second hard mask 118) will be explained. The first hard mask 116 can be exemplified by an amorphous carbon film, whereas a SiOC film or the like can be used as the second hard mask 118. It is to be noted that the hard mask in this embodiment may be a single-layered film.

On the second hard mask 118, the first resist film 120 is then formed. The first resist film 120 is formed by exposing a resist film through the first photomask 106, by an ordinary photolithographic process, as having the first rectangular pattern 104a transferred therein (FIGS. 4A and 4B).

Next, using the resist mask 120 having the first rectangular pattern 104a formed therein as a mask, the second hard mask 118 and the first hard mask 116 are etched by a general method (FIGS. 5A and 5B). By this process, a part of the surface of the polysilicon film 114 is exposed, and a stacked structure of the second hard mask 118a and the first hard mask 116a, having the first rectangular pattern 104a, is formed.

An anti-reflection film 122 is then formed so as to bury the first hard mask 116a and the second hard mask 118a, and so as to cover the entire portion of the polysilicon film 114. On the anti-reflection film 122, a resist film is formed, followed by light exposure using an unillustrated trimming mask and development, so as to remove the resist film selectively in the region right above unnecessary pattern, to thereby form the resist film 124 having a pattern of the trimming mask transferred therein (FIGS. 6A and 6B).

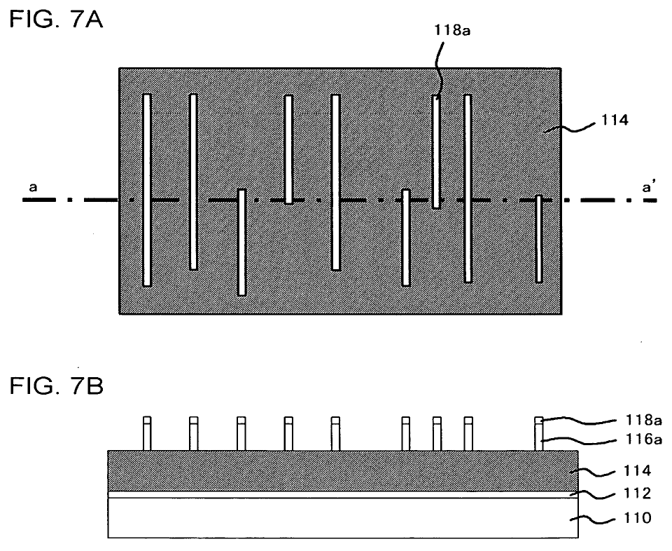

Next, using the resist film 124 as a mask, the anti-reflection film 122, the second hard mask 118a and the first hard mask 116a are selectively removed by etching. The resist film 124 and the anti-reflection film 122 are then removed by a general method, thereby leaving the stacked structure of the second hard mask 118a and the first hard mask 116a composing a desired portion of the first rectangular pattern 104a (FIGS. 7A and 7B).

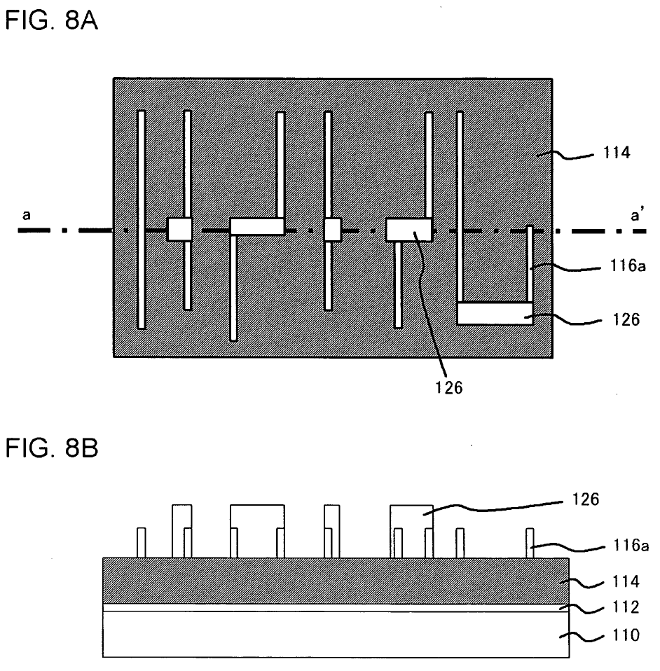

Next, the second hard mask 118a is removed, and a second resist film is formed so as to bury the first hard mask 116a, and so as to cover the entire portion of the polysilicon film 114. The second resist film is then illuminated through the second photomask 108 by a general photolithographic process and developed, thereby forming the second resist film 126 having the second rectangular pattern 104b transferred therein (FIGS. 8A and 8B).

The polysilicon film 114 is then etched using the first hard mask 116a and the resist film 126 as masks. Thereafter, the first hard mask 116a and the resist film 126 are removed by the ordinary process (FIGS. 9A and 9B).

The gate oxide film 112 is then selectively removed by etching, thereby forming the gate electrodes composed of the polysilicon film 114, while leaving the gate oxide film 112 thereunder. The process is then followed by a step forming extension regions in the semiconductor substrate 110, a step forming sidewalls on the side faces of the gate electrodes, a step forming the source/drain regions in the semiconductor substrate 110 and a step forming a silicide layer, thereby fabricating the semiconductor device.

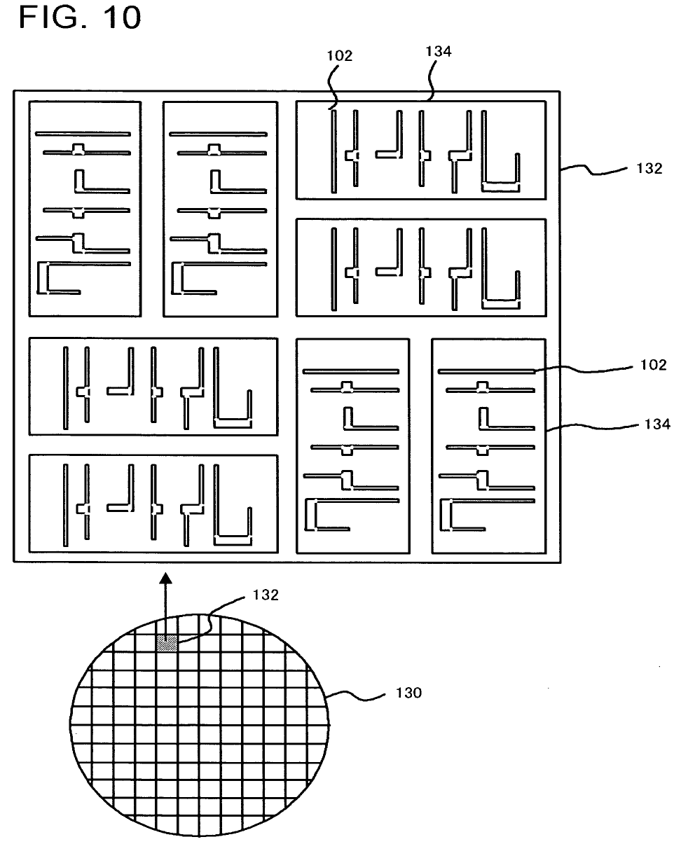

The region having a plurality of transistors 100 arranged therein as described in the above shows only a single region out of a plurality of such regions residing in one chip on a semiconductor wafer. More specifically, as shown in FIG. 10, in one chip 132 on the semiconductor wafer 130, a plurality of the above-described regions 134 can be formed. Each of the regions 134 may be formed as being aligned in a desired direction. So far as the gate patterns 102 are formed so as to unidirectionally align the longitudinal direction thereof in each region 134, the longitudinal directions of the gate patterns 102 may be aligned in desired directions differed among the plurality of regions 134.

While FIG. 10 showed an exemplary case having a plurality of regions 134, it is not always necessary that every region is composed of the region 134. In other words, it is not necessary for all regions to have the same gate patterns, provided that a mask having the rectangular patterns 104a with width “A” unidirectionally aligned therein as shown in FIGS. 3A and 3B can be used for a single region, thereby making it possible to obtain a chip composed of a large number regions containing arbitrary gate patterns.

Effects of this embodiment will be explained below.

This embodiments adopts the first photomask 106 having the first rectangular pattern 104a obtained by dividing the mask pattern 104, and the second photomask 108 having a second rectangular pattern 104b obtained by dividing the mask pattern 104. For this reason, there is no need of carrying out any complicated OPC process, and can thereby improve productivity of the semiconductor devices, and improve the product yield.

In the method of manufacturing a semiconductor device described in Japanese Laid-Open Patent Publication No. 8-227140, the mask pattern was divided into the orthogonal directions, but some regions have the mask patterns aligned in a close proximity in the same direction, raising a need of complicated OPC process for the kinked portions of the mask patterns. For this reason, the mask pattern drawing sometimes took a longer time, resulting in a lowered productivity of the semiconductor devices. It has also been anticipated that unexpected patterns may be formed, and thereby the product yield may be degraded.

In contrast in this embodiment, the mask pattern is divided into rectangular patterns, so that there is no need of carrying out any complicated OPC process which has conventionally been adopted to kinked portions of the mask patterns. The process time of mask pattern drawing can therefore be shortened, and thereby productivity of the semiconductor devices is improved. In addition, getting rid of any complicated OPC process successfully improves the product yield.

Further in this embodiment, the film (polysilicon film 114) is etched using a mask composed of the second resist film 126 having the second rectangular pattern 104b transferred therein, and the hard mask (first hard mask 116a and second hard mask 118) having the first rectangular pattern 104a formed therein.

As described in the above, by forming the first rectangular pattern 104a in the hard mask, the film can be etched as forming the first rectangular pattern 104a in a well-controlled manner. On the other hand, the second rectangular pattern 104b is formed in the second resist film 126. As described in the above, the hard mask is used for the portions in need of accurate transfer of the mask pattern to the film, whereas the second resist film 126 is used for portions where the accuracy is of less importance. By appropriately using the different photomasks depending on required levels of accuracy with respect to transfer of the mask pattern, the light exposure process can be simplified, and thereby the production cost can be reduced.

In this embodiment, the first rectangular pattern 104a and the second rectangular pattern 104b are composed of the mask patterns divided into the orthogonal directions.

Division of the mask pattern into the orthogonal directions can make the mask pattern more simple, so that focus margin in the lithographic process is further expanded, resulting in improvement in the mass productivity.

Further in this embodiment, the minimum value of width “A” of the first rectangular pattern 104a measured in the longitudinal direction thereof is set smaller than the minimum value of width “B” of the second rectangular pattern 104b measured by in the longitudinal direction thereof.

In the design of conventional semiconductor devices, it is general to provide no difference in the width of the orthogonal mask patterns. In other words, it is a general practice to reduce the width of the mask patterns, because there is a need of forming a large number of circuits and so forth in a limited area of regions. Also it is not a general practice to provide limitation on the width of mask patterns depending on directions, because this is considered as not preferable in view of forming a large number of circuits and so forth in a limited area of regions.

In contrast in this embodiment, the mask patterns wished to be formed in a well-controlled manner are aligned in a predetermined direction, and the minimum width thereof is set smaller than the minimum width of the mask pattern for which the controllability is of less importance. By using the different photomasks depending on required levels of transferability of the mask patterns as described in the above, selection of lithographic conditions can be facilitated, resulting in improvement in the productivity. It is also made possible to reduce the cost of manufacturing.

### Second Embodiment

Next, a method of manufacturing a semiconductor device according to the second embodiment will be explained. The first embodiment explained the case where a Levenson-type, phase-shifting mask was used as the first photomask, whereas in the second embodiment, explanation will be made on an exemplary case where both of the first and the second photomasks are binary masks.

In photolithography, resolution enhancement technology is generally adopted in order to form micro-patterns as fine as resolution limit determined by wavelength of light exposure and number of aperture of a projection optical system of an exposure apparatus. The phase-shifting mask is a representative one of the resolution enhancement technology. On the other hand, off-axis illumination can be exemplified as a representative resolution enhancement technology using the binary mask. The off-axis illumination, when classified by geometry of light source, includes annular illumination, quadrupole illumination, dipole illumination and so forth.

This embodiment adopts the binary masks for the first and second photomasks, and annular illumination. Also this embodiment will be explained again referring to the case where the gate patterns 102 same as those in the first embodiment (FIG. 1) are formed.

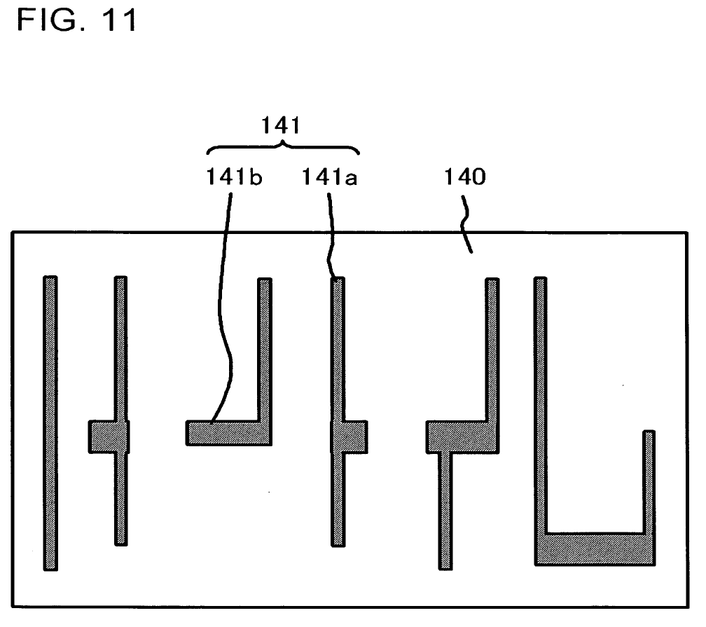

First, as shown in FIG. 11, a binary mask 140 capable of forming a desired mask pattern 141, which is formed on the semiconductor device, is designed.

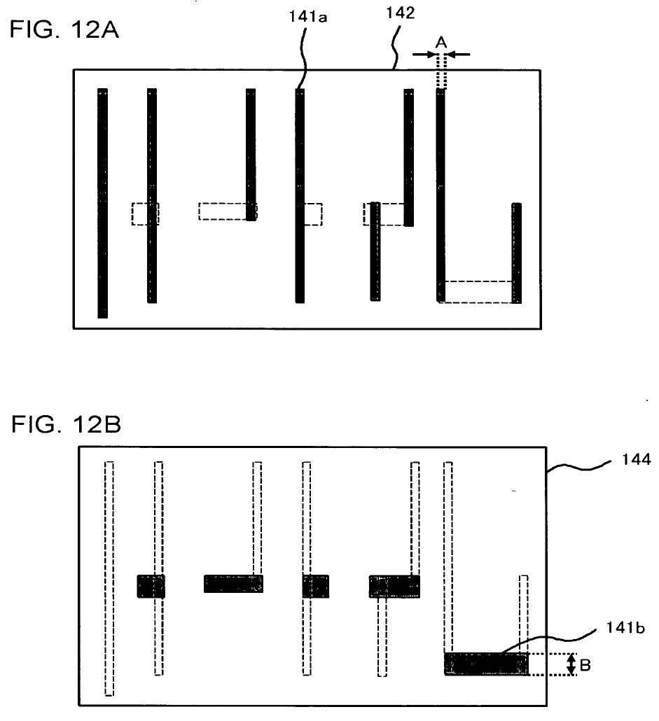

The binary mask 140 is then divided into a first photomask 142 (FIG. 12A) having a first rectangular pattern 141a formed therein, and a second photomask 144 (FIG. 12B) having a second rectangular pattern 141b formed therein. As shown in FIGS. 12A and 12B, the minimum value of width “A” of the first rectangular pattern 141a measured in the longitudinal direction thereof is set smaller than the minimum value of width “B” of the second rectangular pattern 141b measured in the longitudinal direction thereof.

As is clear from the above, neither the first rectangular pattern 141a nor the second rectangular pattern 141b contains the pattern composed of a plurality of rectangles as shown in FIG. 18, so that the OPC process for fabrication of the mask is extremely simplified. As a consequence, also drawing of the mask pattern is simplified, productivity of the semiconductor devices is improved, and thereby the product yield is improved.

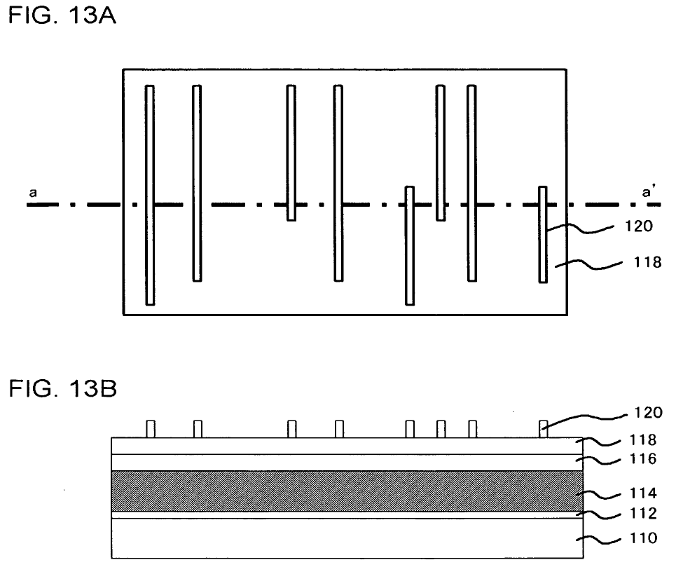

Paragraphs below will explain a method of manufacturing a semiconductor device using the photomasks having the above-described first rectangular pattern 141a and the second rectangular pattern 141b, referring to FIG. 13A to FIG. 17B. In these drawings, the series-A drawings are top views obtained in the method of manufacturing a semiconductor device, and the series-B drawings are correspondent sectional views taken along line a-a′ in the top views of series-A.

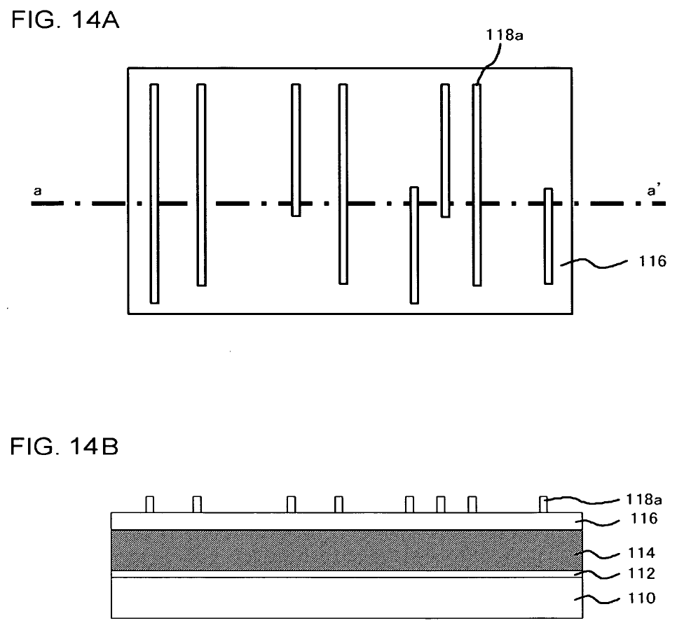

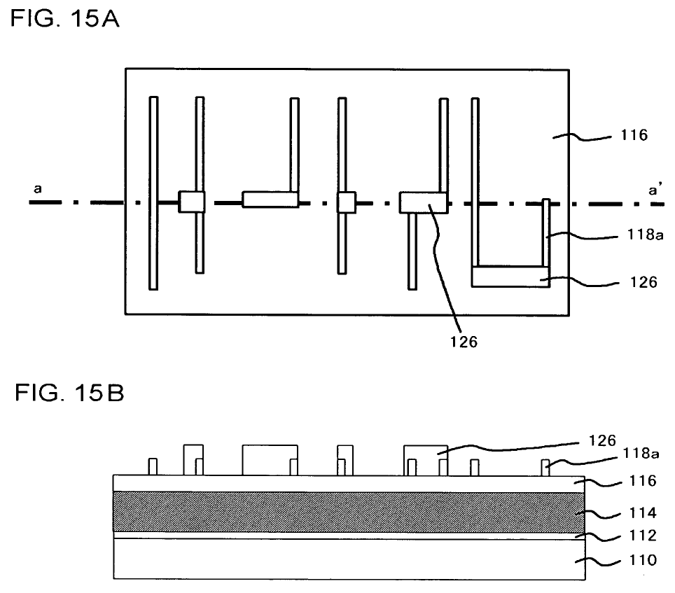

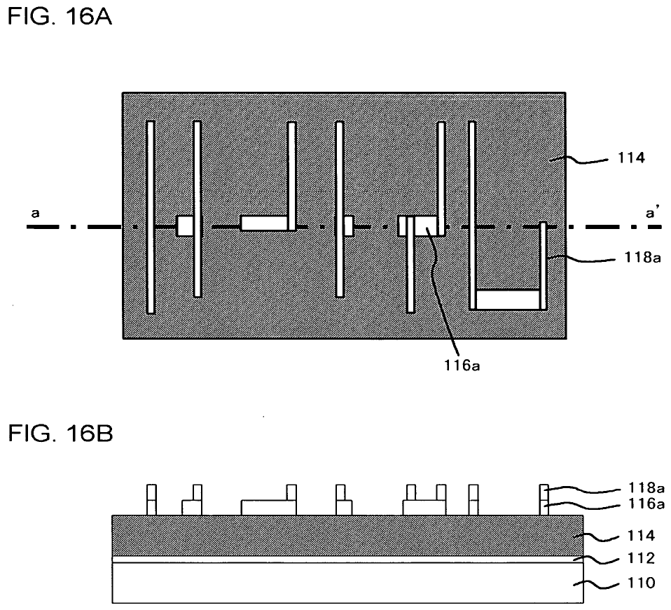

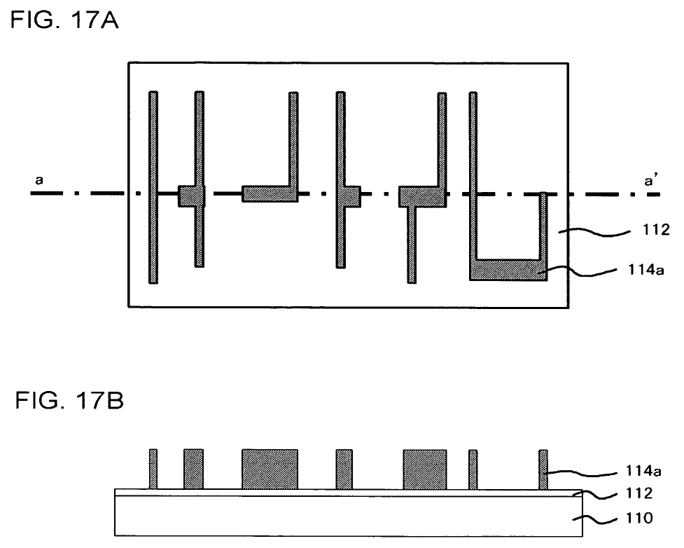

The method of manufacturing a semiconductor device of this embodiment includes three following steps:
(i) a first step forming a first resist film on the first hard mask 116 and the second hard mask 118 formed in this order on the film (polysilicon film 114), exposing the first resist film through the first photomask 142 so as to transfer the first rectangular pattern 141a, and etching the second hard mask 118 using the first resist film 120 having the first rectangular pattern 141a transferred therein (FIG. 13A to 14B);
(ii) a second step forming the second resist film so as to cover the previously-etched second hard mask 118a, exposing the second resist film through the second photomask 144 so as to transfer the second rectangular pattern 141b, and etching the first hard mask 116 using, as masks, the second hard mask 118a having the first rectangular pattern 141a transferred therein and the second resist film 126 having the second rectangular pattern 141b transferred therein (FIGS. 15A to 16B); and
(iii) a third step etching the film (polysilicon film 114) using the first hard mask 116a and the second hard mask 118a as masks (FIGS. 17A and 17B).

In this embodiment, the hard masks (first hard mask 116, second hard mask 118), the first resist film 120, the second resist film 126 and so forth are used as the sacrificial film.

The above-described method of manufacturing a semiconductor device will be detailed below.

First, the gate oxide film 112, the polysilicon film 114 and an insulating film are sequentially stacked on a semiconductor substrate 110. In this embodiment, an exemplary case where the insulating film is composed of the first hard mask 116 and the second hard mask 118 will be explained. The first hard mask 116 can be exemplified by an amorphous carbon film, whereas a SiOC film or the like can be used as the second hard mask 118.

On the second hard mask 118, the first resist film 120 is then formed. The first resist film 120 is formed by exposing a resist film through the first photomask 142, by an ordinary photolithographic process, as having the first rectangular pattern 104a formed therein (FIGS. 13A and 13B).

Next, the second hard mask 118 is selectively etched using, as a mask, the first resist film 120 having the first rectangular pattern 141a formed therein (FIGS. 14A and 14B). The second hard mask 118a having the first rectangular pattern 141a is thus formed.

A resist film is then formed so as to bury the second hard mask 118a, and so as to cover the entire portion of the first hard mask 116. The resist film is then illuminated by an ordinary photolithographic process through the second photomask 144 and developed, thereby forming the second resist film 126 having the second rectangular pattern 141b transferred therein (FIGS. 15A and 15B).

The first hard mask 116 is then etched using the second hard mask 118a and the resist film 126 as masks. By this process, the first rectangular pattern 141a composed of a stacked structure of the first hard mask 116a and the second hard mask 118a, and the second rectangular pattern 141b composed of the first hard mask 116a are formed (FIGS. 16A and 16B).

The polysilicon film 114 is then etched using the first hard mask 116a and the second hard mask 118a as masks. The first hard mask 116a and the second hard mask 118a are then removed (FIGS. 17A and 17B).

The gate oxide film 112 is then selectively removed by etching, thereby forming the gate electrodes composed of the polysilicon film 114, while leaving the gate oxide film 112 thereunder. The process is then followed by a step forming extension regions in the semiconductor substrate 110, a step forming sidewalls on the side faces of the gate electrodes, a step forming the source/drain regions in the semiconductor substrate 110 and a step forming a silicide layer, thereby fabricating the semiconductor device.

Effects of this embodiment will be explained below.

Effects similar to those in the first embodiment are obtainable also by this embodiment. In addition, all mask patterns are transferred to the hard masks, so that the mask patterns are formed with a high accuracy, and thereby reliability of the resultant semiconductor devices is improved. Etching of the second hard mask 118 while keeping a sufficient selectivity against the first hard mask 116 can improve the degree of freedom in the design.

While the embodiments of the present invention have been described referring to the attached drawings, they are merely examples of the present invention, allowing adoption of various configurations other than those described in the above.

For example, the first embodiment was explained referring to the case using the phase-shifting mask, but the mask is not specifically limited, allowing use of a mask for general photolithography. There is no need of using a trimming mask, when a photomask other than the phase-shifting mask is used.

The above-described embodiments were explained referring to the case where the photomask is composed of the first photomask and the second photomask, whereas the photomask may be composed of a still larger number of photomasks.

It is apparent that the present invention is not limited to the above embodiment, that may be modified and changed without departing from the scope and spirit of the invention.

What is claimed is:

1. A method of manufacturing a semiconductor device including a step of transferring a mask pattern using a photomask onto a sacrificial film on a semiconductor substrate, and etching a film formed on said semiconductor substrate using said sacrificial film as a mask,
wherein, as said photomask, a first photomask having a first rectangular pattern obtained by dividing said mask pattern, and a second photomask having a second rectangular pattern obtained by dividing said mask pattern, are used, and
said step includes three following steps of:
a first step processing said sacrificial film using said first photomask to thereby form a first rectangular pattern;
a second step processing said sacrificial film using said second photomask to thereby form a second rectangular pattern; and
a third step etching said film using, as a mask, said sacrificial film processed as having said first and second rectangular patterns formed therein.

2. The method of manufacturing a semiconductor device as claimed in claim 1,
wherein said sacrificial film comprises a hard mask, a first resist film and a second resist film, and
said step includes three following steps of:
a first step forming said first resist film on said hard mask formed on said film, exposing said first resist film through said first photomask so as to transfer said first rectangular pattern, and etching said hard mask using, as a mask, said first resist film having said first rectangular pattern transferred therein;
a second step forming said second resist film so as to cover said hard mask already etched, exposing said second resist film through said second photomask so as to transfer said second rectangular pattern, to thereby form said second resist film having said second rectangular pattern transferred therein, on said film, while retaining thereon said hard mask having said first rectangular pattern transferred therein; and
a third step etching said film, using said second resist film and said hard mask as a mask.

3. The method of manufacturing a semiconductor device as claimed in claim 1,
wherein said sacrificial film comprises a first hard mask, a second hard mask, a first resist film and a second resist film, and
said step includes three following steps of:
a first step forming said first resist film on said first hard mask and said second hard mask formed on said film in this order, exposing said first resist film through said first photomask so as to transfer said first rectangular pattern, and etching said second hard mask using, as a mask, said first resist film having said first rectangular pattern transferred therein;
a second step forming said second resist film so as to cover said second hard mask already etched, exposing said second resist film through said second photomask so as to transfer said second rectangular pattern, and etching said first hard mask using, as masks, said second hard mask having said first rectangular pattern transferred therein, and said second resist film having said second rectangular pattern formed therein; and
a third step etching said film, using, as masks, said first hard mask and said second hard mask.

4. The method of manufacturing a semiconductor device as claimed in claim 1,
wherein said first rectangular pattern and said second rectangular pattern are composed of mask patterns obtained by division in orthogonal directions.

5. The method of manufacturing a semiconductor device as claimed in claim 1,
wherein the minimum value of the width of said first rectangular pattern measured in the direction normal to the longitudinal direction thereof is smaller than the minimum value of the width of said second rectangular pattern measured in the direction normal to the longitudinal direction thereof.

6. The method of manufacturing a semiconductor device as claimed in claim 1,
wherein at least either one of said first photomask and said second photomask is a phase-shifting mask.

7. The method of manufacturing a semiconductor device as claimed in claim 1,
wherein both of said first photomask and said second photomask are binary masks.

8. The method of manufacturing a semiconductor device as claimed in claim 1,
wherein said film is a polysilicon film.
